(19) United States
(12) Patent Application Publication
(10) Pub. No.: US 2016/0353609 A1
(43) Pub. Date: Dec. 1, 2016

(54) Coolant Drain Mechanism of Casing, Electric Storage Device and Construction Machine

(71) Applicant: KOMATSU LTD., Minato-ku, Tokyo (JP)

(72) Inventors: Takahiro Kakizaki, Fujisawa-shi, Kanagawa (JP); Masayuki Konishi, Hiratsuka-shi, Kanagawa (JP)

(21) Appl. No.: 14/770,982

(22) PCT Filed: Mar. 30, 2015
(86) PCT No.: PCT/JP2015/060025

§ 371 Date: Aug. 27, 2015

(51) Int. Cl. H05K 7/20

(52) U.S. Cl. CPC H05K 7/20272

(57) ABSTRACT

A coolant drain mechanism of a casing for draining a coolant from an inside of a cooling channel is provided to a bottom of a casing housing a body to be cooled. A partitioning wall for partitioning the cooling channel into at least a pair of a first channel and a second channel, a drain port opened to both of the first channel and the second channel across the partitioning wall, and a drain stopper attachable to the drain port to seal the drain port are provided to the bottom. A portion of the drain stopper exposed into the cooling channel restrains a flow between the channels at a position where the drain port is in communication with the first channel and the second channel.

### TECHNICAL FIELD

The present invention relates to a coolant drain mechanism of a casing, an electric storage device and a construction machine.

### BACKGROUND ART

A working machine in a form of a hybrid hydraulic excavator that drives working equipment such as a boom, arm and bucket using hydraulic oil from a hydraulic pump driven by an engine, and rotates an upper revolving body with an electric rotating motor has been recently known (see, for instance, Patent Literature 1). FIG. 8 shows an arrangement of a hybrid device used in the hydraulic excavator of Patent Literature 1.

An engine 3 of the hydraulic excavator 1 shown in FIG. 8 is mounted in an engine compartment 2A disposed on a rear side of an upper revolving body 2 in a manner that an axial direction of a crank shaft (not shown) is parallel to a vehicle width direction (i.e. horizontal direction orthogonal to a front-back direction of the vehicle). In addition, a cooling fan 4 for sucking cooling air from an outside into the engine compartment 2A, an engine radiator 5, a hybrid radiator 6 and a plurality of hybrid units that are to be cooled by the sucked cooling air are disposed on a side of the engine 3 in the vehicle width direction sequentially toward the outside.

The hybrid units include a power-generating motor (not shown) disposed on the other side of the engine 3 and driven by the engine 3, a capacitor 7 for storing electric power generated by the power-generating motor, an inverter 8 for controlling storage/supply of the electric power in/from the capacitor 7, and an electric rotating motor 9 driven by the electric power from the capacitor 7. The capacitor 7 and the inverter 8 are provided in a unit together with a terminal box and are disposed at a position accessible through an openable/closable side cover 2B.

The capacitor 7, the inverter 8 and the electric rotating motor 9 are cooled by a dedicated cooling-water circuit including the hybrid radiator 6. The cooling water cooled by the hybrid radiator 6 is initially delivered through a pipe W1 to the capacitor 7 using the cooling water pump P. The cooling water having cooled the capacitor 7 is delivered through a pipe W2 to the inverter 8 disposed on an upper side of the capacitor 7. The cooling water having cooled the inverter 8 is delivered through a pipe W3 to the electric rotating motor 9. The cooling water having cooled the electric rotating motor 9 is delivered through a pipe W4 to be returned to the hybrid radiator 6.

### CITATION LIST

### Patent Literature(s)

Patent Literature 1 JP-A-2012-112102

### SUMMARY OF THE INVENTION

### Problem(s) to be Solved by the Invention

The component to be cooled by the cooling water (e.g. the capacitor 7) disclosed in Patent Literature 1 has a casing, a bottom of which is provided with a cooling channel. The cooling channel has a U-shaped configuration in a plan view so that an inlet In and an outlet Out of the cooling water are provided on the same side of the casing. Specifically, the cooling water flowing into the inlet In on one end of the U-shaped cooling channel turns at 180 degrees to be flowed out of the outlet Out. Accordingly, a partitioning wall for partitioning the cooling channel at the turning point in the flow direction into an upstream channel and a downstream channel is provided to the bottom of the casing. Further, a drain port for draining the cooling water from an inside of the cooling channel for maintenance of the capacitor 7 is provided to each of the upstream channel and the downstream channel. Accordingly, even when the vehicle is stopped in a slightly slanted posture, the cooling water does not remain in each of the channel portions but can be reliably drained through the drain port of at least one of the channels.

There is a demand for efficiently draining the cooling water from the capacitor 7 in order to perform the maintenance work within a short time. Accordingly, enlargement of the diameter of the drain port is desired.

However, though it is desirable to provide each of the drain ports at mutually close positions for the convenience of maintenance, it is not possible to juxtapose two drain ports each having a large diameter due to, for instance, limitation in size of the casing of the capacitor 7.

Further, the drain ports disposed at two positions per se require time and effect for attaching and detaching drain plugs for closing the drain ports, and a solution therefor is desired. Specifically, when the drain plug is to be detached from a second one of the drain ports after the first one of the drain ports is detached, the cooling water from the first one of the drain ports spills on a worker, which deteriorates operability.

It should be noted that the above-described problems may occur not only in the capacitor 7 but also in a casing of the inverter 8 or the other device(s) employing a similar drain structure.

An object of the invention is to provide a coolant drain mechanism of a casing capable of facilitating maintenance, an electric storage device and a construction machine.

### Means for Solving the Problem(s)

A coolant drain mechanism of a casing according to an aspect of the invention includes: a cooling channel provided to a bottom of the casing in which a body to be cooled is housed, a coolant being drained from the cooling channel; a partitioning wall provided on the bottom, the partitioning wall partitioning the cooling channel into at least a pair of a first channel and a second channel; a drain port provided on the bottom, the drain port being opened to both of the first channel and the second channel across the partitioning wall; and a drain stopper being attachable to the drain port to seal the drain port, in which a part of the drain stopper is exposed in the cooling channel, the part of the drain stopper restraining a flow of the coolant between the first channel and the second channel at a position where the drain port is in communication with the first channel and the second channel.

According to the above aspect of the invention, only a single drain port opened (i.e. to be in communication with) to both of the first channel and the second channel only a single drain plug attached to/detached from the drain port are required, the attachment/detachment of the drain plug can be facilitated. Further, since only one drain port is provided, even when the diameter of the drain port is increased, the drain port can be securely provided. The above contributes to improvement in facilitation of maintenance.

In the coolant drain mechanism of the casing according to the above aspect of the invention, it is preferable that a guide portion is provided to a portion of the partitioning wall corresponding to the drain port, a thickness of the guide portion being reduced toward a draining direction of the coolant.

In the coolant drain mechanism of the casing according to the above aspect of the invention, it is preferable that the drain mechanism further includes a bypass plug independent of the partitioning wall, the bypass plug defining a part of the partitioning wall corresponding to the drain port, in which the partitioning wall is provided with a cut where the bypass plug is to be attached.

In the coolant drain mechanism of the casing according to the above aspect of the invention, it is preferable that the cooling channel includes a groove-shaped portion provided to the bottom of the casing and a channel cover covering the groove-shaped portion to define a flow space for the coolant, and an end of the bypass plug opposite the drain port is held by the channel cover.

In the coolant drain mechanism of the casing according to the above aspect of the invention, it is preferable that the bypass plug is made of an elastic material.

An electric storage device according to another aspect of the invention includes a casing employing the above-described coolant drain mechanism

A construction machine according to still another aspect of the invention includes the above electric storage device.

### BRIEF DESCRIPTION OF DRAWING(S)

FIG. 1 is an exploded perspective view showing a capacitor employing a coolant drain mechanism of a casing according to an exemplary embodiment of the invention.

FIG. 2 is a plan view showing a relevant part of the coolant drain mechanism.

FIG. 3 is a cross section showing a relevant part of the coolant drain mechanism seen in a direction indicated by arrows in FIG. 2.

FIG. 4 is a cross section showing the relevant part of the coolant drain mechanism seen in a direction indicated by arrows IV-IV in FIG. 2.

FIG. 5 is a perspective view showing an entirety of a bypass plug used in the coolant drain mechanism.

FIG. 6 is a cross section showing a modification of the exemplary embodiment.

FIG. 7 is a cross section showing another modification of the exemplary embodiment.

FIG. 8 is a perspective view illustrating a related art.

### DESCRIPTION OF EMBODIMENT(S)

Exemplary embodiment(s) of the invention will be described below with reference to the attached drawings.

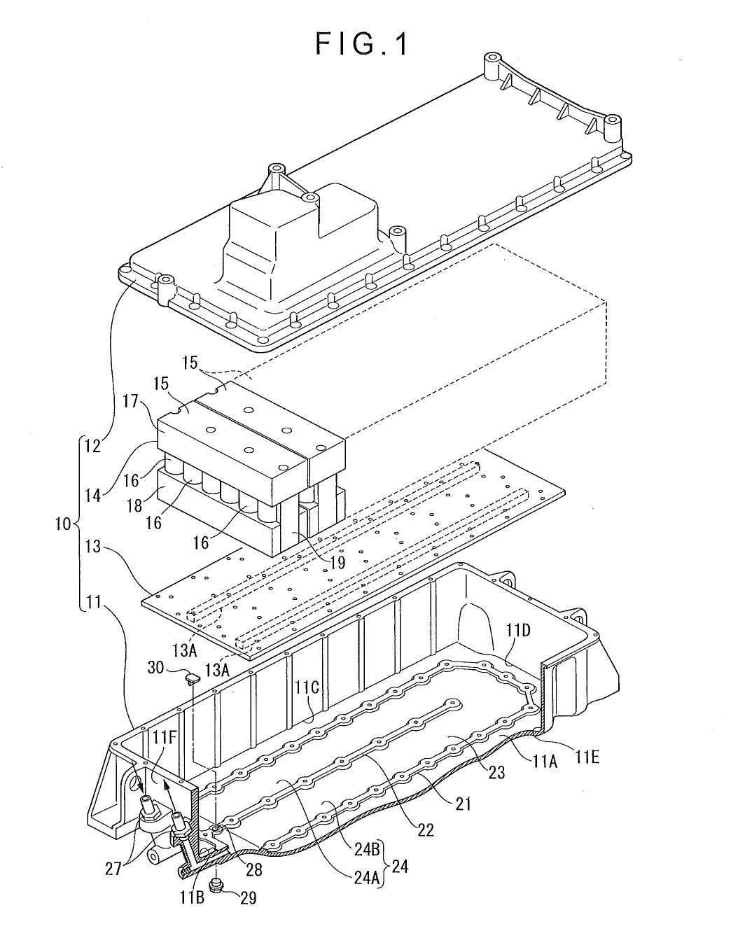

FIG. 1 is an exploded perspective view showing a capacitor (electric storage device) employing a coolant drain mechanism of a casing according to the exemplary embodiment.

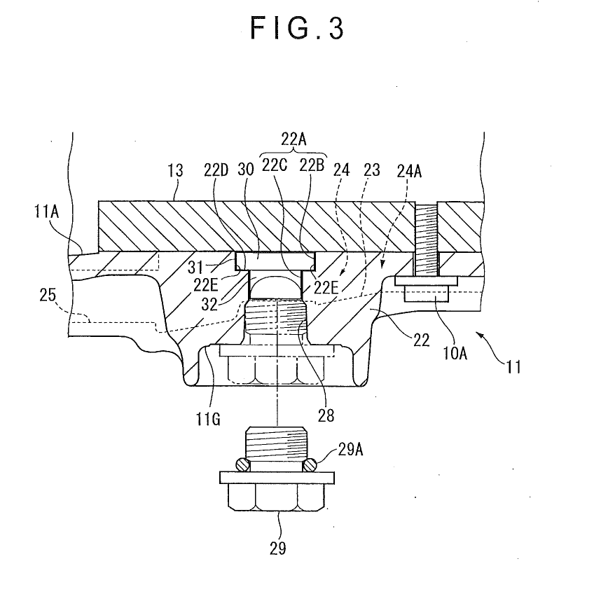

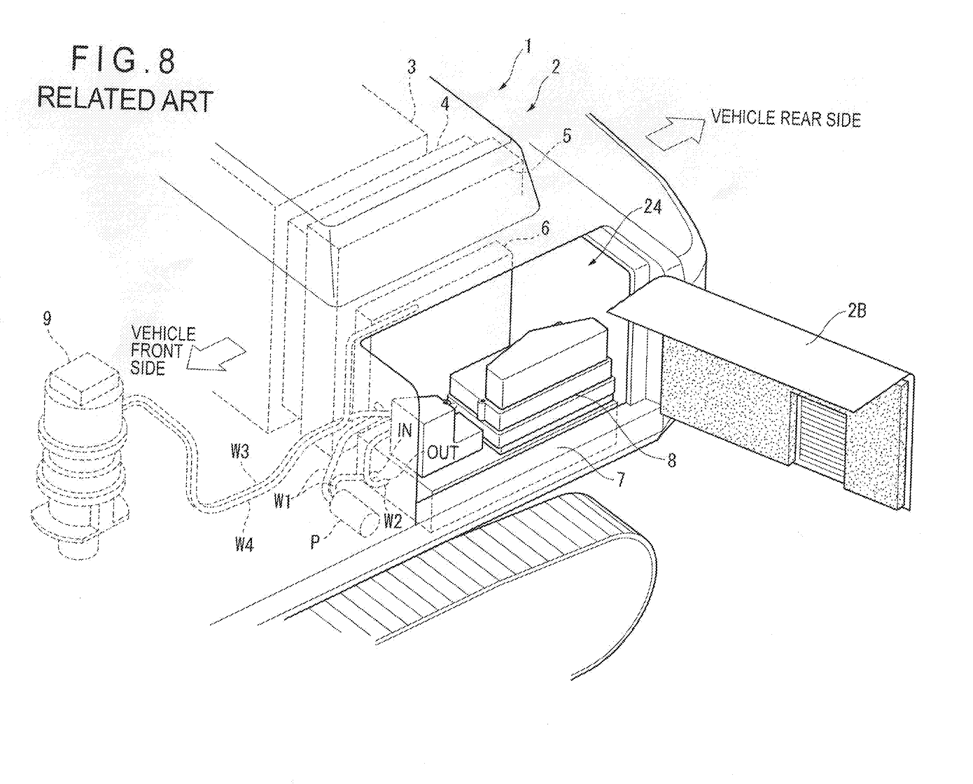

A function and usage of a capacitor 10 shown in FIG. 1 is the same as those of the above-described capacitor 7 described with reference to FIG. 8. The capacitor 10 is mounted in a hybrid hydraulic excavator 1 (construction machine). The capacitor 10 includes: an aluminum die-casting bottomed box-shaped casing 11; an aluminum die-casting casing cover 12 that closes an upper opening of the casing 11; a channel cover 13 that is fixed to a bottom of the casing 11 with a plurality of bolts 10A (see FIG. 3) from a lower side of the casing 11; and a capacitor assembly 14 (body to be cooled) housed in the casing 11. In addition to the above, the capacitor 10 includes a large number of electric wirings for electrically connecting the capacitor assembly 14 with the outside. However, the electric wirings are not shown in FIG. 1.

The channel cover 13 is a component made of aluminum extruded material. The channel cover 13 is provided to a lower side thereof with a plurality of fins 13A extending along an extrusion direction.

The capacitor assembly 14 includes a plurality of capacitor units 15 juxtaposed along a longitudinal direction of the casing 11 having an approximately rectangular parallelepiped shape. Further, each of the capacitor units 15 includes a plurality of capacitor modules 16, and upper and lower holders 17, 18 and aluminum heat sink 19 holding the plurality of capacitor modules 16. Heat generated in the capacitor assembly 14 is transferred to the channel cover 13 via the heat sink 19 to be radiated to cooling water (coolant). It should be noted that the capacitor assembly 14 does not directly relate to the invention and further description thereof will be omitted herein.

An arrangement for the coolant drain structure provided to the casing 11 will be detailed below.

The casing 11 has a bottom 11A provided with an annular outer partition 21 extending along four peripheral edges (sometimes respectively referred to as first, second, third and fourth peripheral edges hereinafter) 11B, 11C, 11D, 11E of the bottom 11A, and an inner partition 22 (partitioning wall) extending approximately from a center of a part of the outer partition 21 along the second short-side edge 11B toward the third short-side edge 11D. An end of the inner partition 22 close to the second short-side edge 11B is continuous with the outer partition 21, whereas an end close to the fourth short-side edge 11D is not continuous with the outer partition 21. The outer partition 21 and the inner partition 22 project from the bottom 11A by a predetermined height. A trough defined by the outer partition 21 and the inner partition defines a groove-shaped portion 23. The channel cover 13 is bolted to upper ends (projection ends) of the outer partition 21 and the inner partition 22 through a liquid sealing to cover the groove-shaped portion 23. The groove-shaped portion 23 and the channel cover 13 covering the groove-shaped portion 23 define a circulation space (i.e. a cooling channel 24) for the cooling water to be circulated. The outer partition 21, which defines an outer periphery of the cooling channel 24, has a substantially rectangular annular shape similar to the shape in a plan view of the capacitor assembly 14 to be cooled.

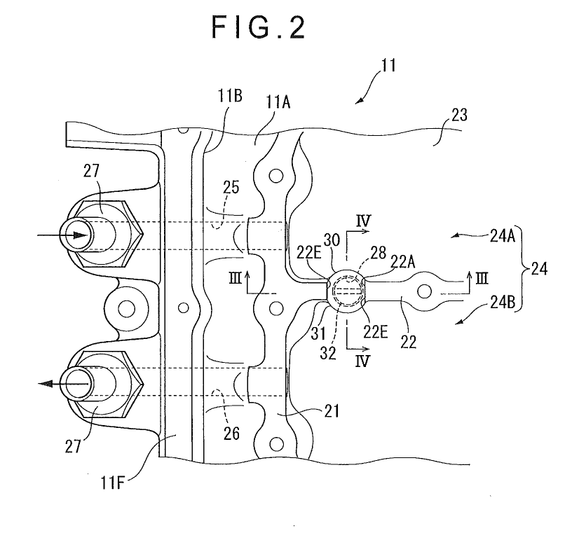

The cooling channel 24, which is in a U-shape in a plan view, includes an upstream first channel portion 24A and a downstream second channel portion 24B partitioned by the center inner partition 22. Channel widths of the first channel portion 24A and the second channel portion 24B are substantially the same. A distance between an end of the inner partition 22 close to the fourth short-side edge 11D and a part of the outer partition 21 extending along the fourth short-side edge 11D is substantially the same as the channel width. The cooling channel 24 includes an inlet portion 25 (see FIG. 2) for introducing the cooling water from a base end of the first channel portion 24A and an outlet portion 26 (see FIG. 2) for discharging the cooling water from a terminal end of the second channel portion 24B. The inlet portion 25 and the outlet portion 26 are both opened at a side wall 11F near the second short-side edge 11B. Pipe joints 27 connected with pipes W1, W2 shown in FIG. 8 are individually provided to the openings of the inlet portion 25 and the outlet portion 26.

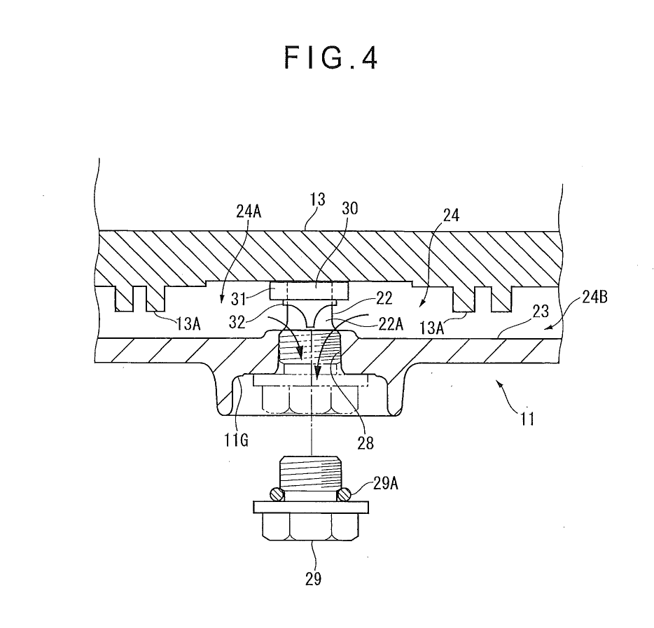

FIG. 2 is a plan view showing a relevant part of the coolant drain mechanism. FIG. 3 is a cross section showing the relevant part of the coolant drain mechanism seen in a direction indicated by arrows in FIG. 2. FIG. 4 is a cross section showing the relevant part of the coolant drain mechanism seen in a direction indicated by arrows IV-IV in FIG. 2.

As shown in FIGS. 2 to 4, a single drain port 28 opened to both of the first channel portion 24A and the second channel portion 24B is provided to the bottom 11A of the casing 11 at a position near the inlet/outlet of the cooling water across the inner partition 22. Accordingly, the cooling water from both of the first channel portion 24A and the second channel portion 24B can be drained through the drain port 28 as shown in arrows in FIG. 4.

At least a part of the drain port 28 is threaded with an internal thread (not shown), to which a bolt-shaped drain plug 29 is screwed from below to seal the drain port 28. An O-ring 29A is attached to the drain plug 29. An abutment face circumferentially in contact with the O-ring 29A is provided to a lower side of the drain port 28. A recess 11G that receives a head of the screwed drain plug 29 is provided to the lower side of the casing 11, thereby restraining the head of the drain plug 29 from colliding with any other component when the capacitor 10 is mounted and restraining a load from directly being applied on the drain plug 29. A space for inserting a tool to be engaged with the head of the drain plug 29 is secured between a circumference of the head of the drain plug 29 and the recess 11G.

A cut 22A dividing the inner partition 22 is provided to the inner partition 22 at a position corresponding to the drain port 28. Accordingly, the aluminum die-casting component is not present above the drain port 28. The cut 22A includes an upper wide part 22B and a lower narrow part 22C. A bottom of the wide part 22B defines a mount base 22D. Further, the wide part 22B includes a pair of opposing inner walls 22E. The inner walls 22E are defined by mutually parallel perpendicular faces. Specifically, the inner walls 22E, 22E are spaced apart from each other along an extending direction of the inner partition 22. A bypass plug 30, which is independent of the other components of the inner partition 22, is attached to the cut 22A. In the exemplary embodiment, the narrow part 22C is defined by a lower hole of the internal thread of the drain port 28. The bypass plug 30 defines a part of the inner partition 22. In other words, the entirety of the inner partition 22 includes the bypass plug 30.

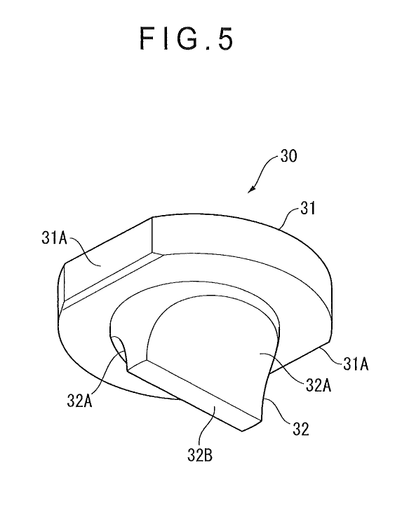

FIG. 5 is a perspective view showing an entirety of the bypass plug 30.

As shown in FIGS. 2 to 5, the bypass plug 30 is provided by an elastic material (e.g. synthetic rubber) as a whole. The bypass plug 30 includes a disc-shaped attachment portion 31 received in the wide part 22B of the cut 22A and having a lower side seated on the mount base 22D, and a guide portion 32 projected downward from the center of the lower side of the attachment portion 31 to be received in the narrow part 22C of the cut 22A.

A pair of parallel flat portions 31A defining width across flats are provided on the outer circumferential surface of the attachment portion 31. The flat portions 31A oppose close to the inner walls 22E of the wide part 22B to serve as a rotation stopper for the bypass plug 30.

An upper (base) end of the guide portion 32 is shaped cylindrical to allow easy insertion into the narrow part 22C, whereas a lower part of the guide portion 32 (i.e. in the drain direction of the cooling water) is thinned. The part of the guide portion 32 at which the thickness changes is defined by an opposite pair of arc portions 32A. A lower end surface 32B of the guide portion 32 has a thin belt shape. A lower end of each of the arc portions 32A defines a long-side edge (i.e. longitudinal edge) of the lower end surface 32B and the longitudinal direction of the lower end surface 32B is orthogonal to the flat portions 31A.

The bypass plug 30 is attached to the cut 22A from above in such a manner that the flat portion 31A faces the inner wall 22E. At this time, as shown in FIG. 3, the bypass plug 30 is attached to the cut 22A so that the longitudinal direction of the lower end surface 32B aligns with the flow direction of the cooling water flowing in the first channel portion 24A and the second channel portion 24B (i.e. along the inner partition 22). The bypass plug 30 attached to the cut 22A is held or pressed by the channel cover 13, which covers a side of the bypass plug 30 opposite the side facing the drain port 28, to be kept from detachment.

The dimension of each of the components is designed so that, when the drain plug 29 is attached, an upper end of the drain plug 29 and the lower end surface 32B of the bypass plug 30 closely face each other in the cooling channel 24. As a result, the cut 22A is substantially completely closed by the drain plug 29 and the bypass plug 30. Accordingly, when the cooling water flows in the first channel portion 24A and the second channel portion 24B, little cooling water flows between the first channel portion 24A and the second channel portion 24B through the cut 22A.

In contrast, when the drain plug 29 is detached to drain the cooling water, a lower side of the bypass plug 30 is opened as shown in FIG. 4. Accordingly, the cooling water from the first channel portion 24A and the second channel portion 24B flows toward the drain port 28 along the guide portion 32 of the bypass plug 30 to be drained through the drain port 28.

The above-described exemplary embodiment provides the following advantages.

The casing 11 of the capacitor 10 includes the single drain port 28 to be in communication with both of the first channel portion 24A and the second channel portion 24B and the single drain plug 29 attached to/detached from the drain port 28, so that attachment/detachment of the drain plug 29 can be facilitated. Further, since only the single drain port 28 is provided, the drain port 28 can be reliably provided even when the diameter of the drain port 28 is enlarged, so that the cooling water can be smoothly drained. The above contributes to improvement in facilitation of maintenance.

Further, since the upper end of the drain plug 29 exposed to the interior of the cooling channel 24 closely faces the lower end surface 32B of the bypass plug 30, the cooling water hardly flows through between the drain plug 29 and the bypass plug 30 when the drain plug 29 is attached (i.e. during normal operation). Accordingly, the bypass flow of the cooling water between the first channel portion 24A and the second channel portion 24B can be prevented, thereby reliably cooling the capacitor assembly 14 with the cooling water.

Since the guide portion 32 of the bypass plug 30 is configured to reduce the thickness thereof toward the flow of the cooling water, the cooling water can be smoothly drained along the arc portions 32A. Further, since the guide portion 32 has the arc portions 32A, a reduction in the cross section of the channel along the drain direction can be avoided.

The bypass plug 30 is independent of the other components of the inner partition 22. Accordingly, a complicated shape (e.g. for the attachment portion 31, the guide portion 32 and the arc portion 32A) can be easily given to the bypass plug 30.

Further, since the bypass plug 30 is made of an elastic material such as synthetic rubber, the bypass plug 30 with a complicated shape can be easily produced through a molding process. Further, even when the upper end of the drain plug 29 accidentally collides with the lower end surface 32B, the drain plug 29 and the bypass plug 30 can be kept from being damaged.

Further, since the cooling channel 24 is defined by the groove-shaped portion 23 provided to the bottom 11A of the casing 11 and the channel cover 13 covering the groove-shaped portion 23, the casing 11 can be manufactured though a die-casting process with a higher accuracy than a gravity die-casting using a core.

It should be understood that the scope of the present invention is not limited to the above-described exemplary embodiment(s) but includes modifications and improvements as long as the modifications and improvements are compatible with the invention.

For instance, the material of the bypass plug may be metal or alternatively be a synthetic resin other than synthetic rubber.

It is not necessary that the bypass plug is a disc-shaped component having width across flats, but the bypass plug may be oblong or rectangular as long as being capable of engagement with the inner wall(s) of the cut. The guide portion of the bypass plug may be provided with a simple flat slanted face instead of the arc portion.

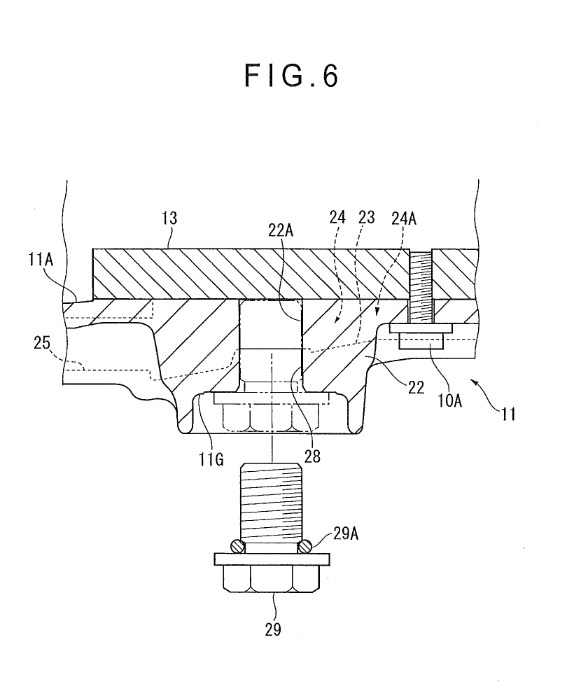

The bypass plug is not requisite in the invention but may be omitted. In this case, the inner partitioning wall may be retained without being divided and an upper end of the drain plug exposed through the opening face of the drain port may be substantially flush with the bottom of the cooling channel to bring the upper end of the drain plug close to the lower side of the inner partitioning wall in the cooling channel. Alternatively, as shown in FIG. 6, a cut 22A for dividing the inner partition 22 may be provided to the inner partition 22 and a half-divided internal thread (not shown) may be provided to the inner wall of the cut 22A. Further, a drain plug 29 having a long external thread portion may be used to mate the drain plug 29 with the drain port 28 and the cut 22A, thereby bringing the upper end of the drain plug 29 close to the lower side of the channel cover 13. Such a cut may be provided to extend to a middle of the inner partitioning wall in a vertical direction so that the cut opens to a lower side of the inner partitioning wall, and a top side of the cut may be brought close to the upper end of the drain plug.

The coolant is not necessarily water but may alternatively be a non-freezing fluid or the like.

The drain port may be provided at any position. For instance, the drain port may be provided at a position corresponding to a center of the inner partitioning wall in the extending direction thereof.

The drain stopper is not necessarily the drain plug but may alternatively be an openable/closable drain cock.

The channel portion defining the cooling channel does not necessarily include the first and second channels continuous in a U-shape but may alternatively have an arrangement in which first to third channel portions are disposed in an N-shape in a plan view. Further alternatively, four or more channel portions may be provided Further, a plurality of channel portions may be independently provided. In this case, an inlet may be provided at one end of each of the channel portions, an outlet may be provided at the other end of each of the channel portions, and the partitioning wall of the invention may be defined by a partition of each of the channel portions.

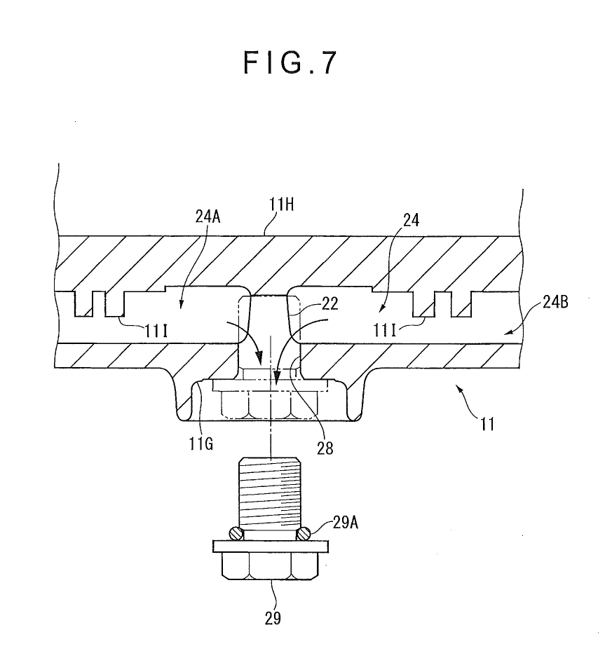

Further, as shown in FIG. 7, the casing 11 may be manufactured using a gravity die-casting using a core without providing the channel cover. Specifically, the drain port 28 may be provided close to the top surface of the cooling channel 24 to divide the inner partition 22 and the upper end of the drain plug 29 may be brought close to the top surface. It should be noted that a fin HI hanging down into the cooling channel 24 can be provided to a bottom 11H of the casing 11 using a core. Further, even when a channel cover is required, almost all of an outer shell of the casing may be manufactured through die-casting and the groove-shaped portion may be provided by machining or the like.

The casing may be used for housing an inverter or any other to-be-cooled body that is necessary to be cooled.

The invention is applicable to a capacitor or an inverter for a hybrid construction machine other than a hydraulic excavator, and to a capacitor or an inverter for a hybrid on-road truck or passenger vehicle.

### EXPLANATION OF CODE(S)

1 . . . hydraulic excavator (construction machine), 10 . . . capacitor (electric storage device), 11 . . . casing, 11A . . . bottom, 13 . . . channel cover, 14 . . . capacitor assembly (body to be cooled), 22 . . . inner partitioning wall (partitioning wall), 22A . . . cut, 23 . . . groove-shaped portion, 24 . . . cooling channel portion, 24A . . . first channel portion 24B . . . second channel. 28 . . . drain port, 29 . . . drain plug (drain stopper), 30 . . . bypass plug, 32 . . . guide portion.

1. A coolant drain mechanism of a casing, comprising:
a cooling channel provided to a bottom of the casing in which a body to be cooled is housed, a coolant being drained from the cooling channel;
a partitioning wall provided on the bottom, the partitioning wall partitioning the cooling channel into at least a pair of a first channel and a second channel;
a drain port provided on the bottom, the drain port being opened to both of the first channel and the second channel across the partitioning wall; and
a drain stopper being attachable to the drain port to seal the drain port, wherein
a part of the drain stopper is exposed in the cooling channel, the part of the drain stopper restraining a flow of the coolant between the first channel and the second channel at a position where the drain port is in communication with the first channel and the second channel.

2. The coolant drain mechanism of the casing according to claim 1, further comprising:
a guide portion is provided to a portion of the partitioning wall corresponding to the drain port, a thickness of the guide portion being reduced toward a draining direction of the coolant.

3. The coolant drain mechanism of the casing according to claim 1, further comprising:
a bypass plug independent of the partitioning wall, the bypass plug defining a part of the partitioning wall corresponding to the drain port, wherein
the partitioning wall is provided with a cut where the bypass plug is to be attached.

4. The coolant drain mechanism of the casing according to claim 3, wherein
the cooling channel includes a groove-shaped portion provided to the bottom of the casing and a channel cover covering the groove-shaped portion to define a flow space for the coolant, and
an end of the bypass plug opposite the drain port is held by the channel cover.

5. The coolant drain mechanism of the casing according to claim 3, wherein:
the bypass plug is made of an elastic material.

6. An electric storage device comprising a casing employing the coolant drain mechanism according to claim 1.

7. A construction machine comprising the electric storage device according to claim 6.
